(19) United States
(12) Patent Application Publication
(10) Pub. No.: US 2010/0035182 A1
(43) Pub. Date: Feb. 11, 2010

(54) PHOTOSENSITIVE RESIN COMPOSITION

(75) Inventors: Ryutaro Tanaka, Tokyo (JP); Makoto Uchida, Tokyo (JP); Kenji Sekine, Tokyo (JP)

Correspondence Address: Nields, Lemack & Frame, LLC, 176 E. Main Street, Suite #5, Westborough, MA, 01581, US

(73) Assignee: Nippon Kayaku Kabushiki Kaisha, Chiyoda-ku, Tokyo (JP)

(21) Appl. No.: 12/450,319

(22) PCT Filed: Apr. 7, 2008
(86) PCT No.: PCT/JP2008/056855

§ 371 Date: Sep. 21, 2009

(30) Foreign Application Priority Data
Apr. 10, 2007 (JP) 2007-102303

(51) Int. Cl. G03F 7/004

(52) U.S. Cl. 430/280.1

(57) ABSTRACT

The present invention relates to a positive type photosensitive polyimide resin composition comprising a phenolic hydroxy group-containing soluble polyimide resin (A) formed from a tetrabasic acid dianhydride (a), an aminophenol compound having at least two amino groups and at least one phenolic hydroxy group in one molecule (b), and a diamino compound (c); a diazo-based positive type photosensitizer (B); and an epoxy resin (C). Using the positive type photosensitive polyimide resin composition of the present invention, a resin composition which allows easy patterning, satisfies various properties such as flame retardancy, heat resistance, mechanical properties and flexibility, and is capable of coping with high functionalization of various electronic devices, and a cured product thereof can be provided.

### TECHNICAL FIELD

The present invention relates to a positive type photosensitive polyimide resin composition developable with an aqueous alkaline solution, and a cured product thereof. The cured product of this composition has excellent flame retardancy and heat resistance even though it does not contain a halogen-based flame retardant, an antimony compound or a phosphorus-based compound, and has sufficient flexibility and storage stability, and thus the cured product is useful as a solder mask for thin package substrates, a coverlay for flexible printed circuit boards, an interlayer insulating film for multilayer printed circuit boards, a semiconductor passivation film, or the like.

### BACKGROUND ART

Currently, solder masks for some printed circuit boards for consumer use and most of industrial printed circuit boards utilize, from the viewpoints of high precision and high density, a photo- (and/or thermo-) curable resin composition which is exposed using a photolithographic method, and then subjected to a development treatment to form an image, and to finish-curing by heating and/or photoirradiation. Furthermore, in consideration of environmental problems, alkali development type liquid solder masks using a dilute aqueous alkaline solution as a developer have become the mainstream. In particular, the solder masks or coverlays applied to ball-grid array substrates or flexible substrates are required to have flexibility, as this material, a composition using a compound obtained by reacting a polyfunctional bisphenol epoxy resin having a flexible structure and a reaction product of (meth)acrylic acid, with a polybasic acid anhydride, has been suggested in Patent Document 1.

Meanwhile, polyimides have excellent heat resistance, flame retardancy, flexibility, mechanical properties, electrical properties and chemical resistance, and thus are widely used in electric/electronic elements, semiconductor, telecommunication equipments and circuit elements thereof, and peripheral equipments. However, since polyimide resins are sparingly soluble in organic solvents, a method of coating a substrate with polyamic acid which is a precursor of polyimide, drying the coating film, then perform patterning through exposure and development, and subsequently heating at about 350° C. to dehydrate is being used (Patent Document 2). Patent Document 3 describes a positive type block-copolymerized polyimide composition which does not contain an epoxy compound, and the document states about a resin composition which does not require dehydration ring closure and can be developed with an aqueous alkaline solution.

Patent Document 1: Japanese Patent No. 2868190

Patent Document 2: JP 6-273932 A

Patent Document 3: WO 2003/060010

### DISCLOSURE OF THE INVENTION

### Problems to be Solved by the Invention

When a cured product of the solder mask composition disclosed in Patent Document 1 is used, the photosensitivity is excellent, development using a dilute aqueous alkaline solution is possible, and the crack resistance of the surface is improved. However, there were problems that it was flammable and still insufficient in flexibility, and extreme bending was unable to follow.

Furthermore, the photosensitive polyimide precursor composition disclosed in Patent Document 2 has excellent post-cure properties, but had problems that the storage stability was low, and contraction caused by dehydration occurs vigorously at the time of the ring closure reaction. The block-copolymerized polyimide composition disclosed in Patent Document 3 does not require dehydration ring closure, but is not satisfactory in terms of developability, resolution property, adhesiveness, heat resistance and the like.

An object of the present invention is to provide a resin composition which can cope with high functionalization of various electronic equipments today, and satisfies various properties such as flame retardancy, heat resistance, mechanical properties and flexibility, and a cured product thereof.

### Means to Solve the Problems

The inventors of the present invention devotedly study the above-described problems, and as a result, finally completed the present invention.

Thus, the present invention relates to the following:

(1) A positive type photosensitive polyimide resin composition comprising a phenolic hydroxy group-containing soluble polyimide resin (A) obtained by subjecting a tetrabasic acid dianhydride (a), an aminophenol compound having at least two amino groups and at least one phenolic hydroxy group in one molecule (b) (hereinafter, may also be simply referred to as aminophenol compound (b)), and a diamino compound (c) to a polycondensation reaction; a diazo-based positive type photosensitizer (B); and an epoxy resin (C);

(2) The positive type photosensitive polyimide resin composition according to (1) above, wherein the tetrabasic acid dianhydride (a) is one or more selected from the group consisting of 3,3′,4,4′-diphenylsulfonetetracarboxylic acid dianhydride, 3,3′,4,4′-benzophenonetetracarboxylic acid dianhydride, 3,3′,4,4′-biphenyltetracarboxylic acid dianhydride, and 3,3′,4,4′-diphenyl ether tetracarboxylic acid dianhydride;

(3) The positive type photosensitive polyimide resin composition according to (1) or (2) above, wherein the aminophenol compound (b) is one or more selected from the group consisting of 3,3′-diamino-4,4′-dihydroxydiphenylsulfone, 3,3′-diamino-4,4′-dihydroxydiphenyl ether, 3,3′-diamino-4,4′-dihydroxybiphenyl, 3,3′-dihydroxy-4,4′-diaminobiphenyl, 2,2-bis(3-amino-4-hydroxyphenyl)propane, 1,3-hexafluoro-2,2-bis(3-amino-4-hydroxyphenyl)propane and 9,9′-bis(3-amino-4-hydroxyphenyl)fluorene;

(4) The positive type photosensitive polyimide resin composition according to any one of (1) to (3) above, wherein the diamino compound (c) is one or more selected from the group consisting of 3,4′-diaminodiphenyl ether, 4,4′-diaminodiphenyl ether, 1,3-bis-(3-aminophenoxy)benzene and a silicone diamine;

(5) The positive type photosensitive polyimide resin composition according to any one of (1) to (4) above, wherein the hydroxy group equivalent of the phenolic hydroxy group-containing soluble polyimide resin (A) is 200 to 5,000 g/eq;

(6) The positive type photosensitive polyimide resin composition according to any one of (1) to (5) above, wherein the epoxy resin (C) is an epoxy resin having a biphenyl skeleton;

(7) The positive type photosensitive polyimide resin composition according to (6) above, wherein the epoxy resin (C) having a biphenyl skeleton has the following formula (1):

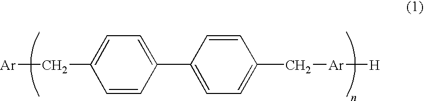

wherein n represents the average value of a repeating number of from 1 to 10;

Ar is a monovalent or divalent residue of a compound represented by the following formula (2) or the following formula (3):

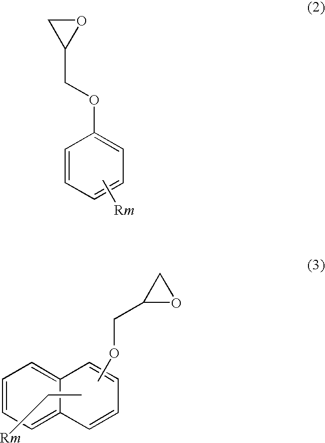

m is an integer from 1 to 3, and represents the number of substituent R;

Rs represent any of a hydrogen atom, a halogen atom, a hydrocarbon group having 1 to 15 carbon atoms, a trifluoromethyl group, an allyl group and an aryl group, respectively;

when m is 2 or 3, individual Rs may be identical with or different from each other; and

Ar may be identical or different, and when Ar is different, the groups of formula (2) and (3) are arranged in an arbitrary order;

(8) A cured product formed by curing the positive type photosensitive polyimide resin composition according to any one of (1) to (7) above;

(9) A substrate having a layer of the cured product according to (8) above;

(10) The positive type photosensitive polyimide resin composition according to (1) above, wherein the tetrabasic acid dianhydride (a) is one or more selected from the group consisting of 3,3′,4,4′-diphenylsulfonetetracarboxylic acid dianhydride, 3,3′,4,4′-benzophenonetetracarboxylic acid dianhydride, 3,3′,4,4′-biphenyltetracarboxylic acid dianhydride and 3,3′,4,4′-diphenyl ether tetracarboxylic acid dianhydride; the aminophenol compound (b) is one or more selected from the group consisting of 3,3′-diamino-4,4′-dihydroxydiphenylsulfone, 3,3′-diamino-4,4′-dihydroxydiphenyl ether, 3,3′-diamino-4,4′-dihydroxybiphenyl, 3,3′-dihydroxy-4,4′-diaminobiphenyl, 2,2-bis(3-amino-4-hydroxyphenyl)propane, 1,3-hexafluoro-2,2-bis(3-amino-4-hydroxyphenyl)propane and 9,9′-bis(3-amino-4-hydroxyphenyl)fluorene; and the diamino compound (c) is one or more selected from the group consisting of 3,4′-diaminodiphenyl ether, 4,4′-diaminodiphenyl ether, 1,3-bis-(3-aminophenoxy)benzene and a silicone diamine;

(11) The positive type photosensitive polyimide resin composition according to any one of (1) to (10) above, wherein the diamino compound (c) is 3,4′-diaminodiphenyl ether, 4,4′-diaminodiphenyl ether or 1,3-bis-(3-aminophenoxy)benzene;

(12) The positive type photosensitive polyimide resin composition according to any one of (1) to (11) above, wherein the aminophenol compound (b) is 3,3′-diamino-4,4′-dihydroxydiphenylsulfone, 3,3′-diamino-4,4′-dihydroxydiphenyl ether or 1,3-hexafluoro-2,2-bis(3-amino-4-hydroxyphenyl)propane;

(13) The positive type photosensitive polyimide resin composition according to (10) above, wherein the tetrabasic acid dianhydride (a) is one or more selected from the group consisting of 3,3′,4,4′-diphenylsulfonetetracarboxylic acid dianhydride, 3,3′,4,4′-benzophenonetetracarboxylic acid dianhydride and 3,3′,4,4′-diphenyl ether tetracarboxylic acid dianhydride; the aminophenol compound (b) is one or more selected from the group consisting of 3,3′-diamino-4,4′-dihydroxydiphenylsulfone, 3,3′-diamino-4,4′-dihydroxydiphenyl ether and 1,3-hexafluoro-2,2-bis(3-amino-4-hydroxyphenyl)propane; and the diamino compound (c) is one or more selected from the group consisting of 3,4′-diaminodiphenyl ether and 1,3-bis-(3-aminophenoxy)benzene;

(14) The positive type photosensitive polyimide resin composition according to any one of (10) to (13) above, wherein the epoxy resin (C) is an epoxy resin having a biphenyl skeleton;

(15) The positive type photosensitive polyimide resin composition according to any one of (1) to (7) and (10) to (14) above, wherein the diazo-based positive type photosensitizer (B) is diazonaphthoquinonesulfonyl ester;

(16) The positive type photosensitive polyimide resin composition according to any one of (1) to (7) and (10) to (14) above, being a resin solution comprising a solvent capable of dissolving the phenolic hydroxy group-containing soluble polyimide resin (A); and

(17) The positive type photosensitive polyimide resin composition according to any one of (1) to (7) and (10) to (14) above, wherein the phenolic hydroxy group-containing soluble polyimide resin (A) has amino groups at both terminals of the resin.

### EFFECT OF THE INVENTION

The positive type photosensitive polyimide resin composition of the present invention has excellent storage stability, developability and resolution property, and a cured product thereof has excellent adhesiveness, solvent resistance, acid resistance, flame retardancy and heat resistance, and also has sufficient flexibility. Therefore, the resin composition and a cured product thereof of the present invention are useful in a wide range of applications such as a solder mask for thin package substrates, a coverlay for flexible printed circuit boards, an interlayer insulating film for multilayer printed circuit boards and a semiconductor passivation film.

### BEST MODE FOR CARRYING OUT THE INVENTION

The phenolic hydroxy group-containing soluble polyimide resin (A) (hereinafter, may also be simply referred to as soluble polyimide resin (A)) of the present invention is obtained by allowing a tetrabasic acid dianhydride (a), an aminophenol compound having at least two amino groups and at least one phenolic hydroxy group in one molecule (b) (hereinafter, may also be simply referred to as aminophenol compound (b)), and a diamino compound (c) to react. When the number of the acid anhydride groups in one molecule of the tetrabasic acid dianhydride (a) and the mole number of the tetrabasic acid dianhydride (a) are designated as X and x, respectively; the number of amino groups in one molecule and the mole number of the aminophenol compound (b) are designated as Y and y, respectively; and the mole number of the diamino compound (c) is designated as z, if Xx>Yy+2z, the terminals are acid anhydride groups, whereas if Xx<Yy+2z, the terminals are amino groups. At this time, it is preferable that the value of Xx/(Yy+2z) is in the range of 0.5 to 2, and more preferably in the range of 0.7 to 1.5. The value is even more preferably 0.8 or more and less than 1, and most preferably in the range of 0.9or more and less than 1, and in this case, the both terminals of the obtained polyimide are amino groups. If the value is less than 0.5 or more than 2, the molecular weight is small, and unreacted raw materials are remained as well, thus various properties such as post-cure heat resistance and flexibility can not be obtained. It is also preferable to introduce the aminophenol compound (b) such that the phenolic hydroxy group equivalent of the phenolic hydroxy group-containing soluble polyimide resin (A) obtained by the reaction is in the range of 200 to 5,000 g/eq. If the equivalent is less than 200 g/eq, acidity becomes strong, and thus film thinning or peel-off occur at the time of development with an aqueous alkaline solution. If the equivalent exceeds 5,000 g/eq, the alkali developability largely deteriorates.

Additionally, in the present invention, the term “soluble polyimide resin” is used to mean a solvent-soluble polyimide resin.

The phenolic hydroxy group-containing soluble polyimide resin (A) of the present invention is synthesized by a simple dehydration condensation reaction between an acid anhydride structure and an amino group. Thus, the feed amounts of the tetrabasic acid dianhydride (a), aminophenol compound (b) and diamino compound (c) required for the synthesis of a phenolic hydroxy group-containing soluble polyimide resin (A) having the intended terminal structure (acid anhydride group or amino group) and hydroxy group equivalent, can be easily calculated from the respective molecular weights, the number of acid anhydride structures, the number of amino groups and the number of phenolic hydroxy groups per molecule, respectively, of (a) to (c).

As an example, for example, in a combination of ODPA (3,3′,4,4′-diphenyl ether tetracarboxylic acid dianhydride, molecular weight 310.22) which is the tetra basic acid dianhydride having two acid anhydride structures in one molecule (a), ABPS (3,3′-diamino-4,4′-dihydroxydiphenylsulfone, molecular weight 280.30) which is the aminophenol compound having two amino groups and two phenolic hydroxy groups in one molecule (b), and APB-N (1,3-bis-(3-aminophenoxy)benzene, molecular weight 292.34) which is the diamino compound (c), which are used as the raw material of the phenolic hydroxy group-containing soluble polyimide resin (A) in Synthesis Example 1 of the present invention, if it is desired to have amine at the terminals of the phenolic hydroxy group-containing soluble polyimide resin (A), ABPS and APB-N may be used in a total amount of 1 mole or more and 2 moles or less relative to 1 mole of ODPA. Also, at this time, in order to adjust the phenolic hydroxy group equivalent of the phenolic hydroxy group-containing soluble polyimide resin (A) in the range of 200 to 5,000 g/eq, for example, when ABPS and APB-N are used in a total amount of 1 mole relative to 1 mole of ODPA, approximately 0.06 moles or more (less than 1 mole) of ABPS may be used; when ABPS and APB-N are used in a total amount of 1.5 moles relative to 1 mole of ODPA, approximately 0.08 moles or more (less than 1.5 moles) of ABPS may be used; and when ABPS and APB-N are used in a total amount of 2 moles relative to 1 mole of ODPA, approximately 0.09 moles or more (less than 2.0 moles) of ABPS may be used.

As the tetrabasic acid dianhydride (a) used for the production of the phenolic hydroxy group-containing soluble polyimide (A), any compound having two acid anhydride structures in a molecule can all be used.

As the tetrabasic acid dianhydride (a), an aromatic tetracarboxylic acid dianhydride is preferred. More preferably, the compound is a compound having one to two benzene rings. Even more preferably, if the acid dianhydride has one benzene ring, the compound is a compound having two acid anhydride groups on one benzene ring, whereas if the acid dianhydride has two benzene rings, the compound is an aromatic tetracarboxylic acid dianhydride in which two phenyl groups, each having one acid anhydride group, are bound directly, or through a bridging group, or as a condensed ring. The bridging group in this case is preferably —O—, —CO—, or —SO₂—, and most preferably —SO₂—. Among the above-described more preferred compounds, an aromatic tetracarboxylic acid dianhydride in which two phenyl groups each having one acid anhydride group are bound directly or through —O—, —CO— or —SO₂—, is preferred, and an aromatic tetracarboxylic acid dianhydride having the two phenyl groups bound through the above-mentioned preferred bridging group, is more preferred.

Specific examples of the tetrabasic acid dianhydride (a) include pyromellitic anhydride, ethylene glycol-bis(anhydrotrimellitate), glycerin-bis(anhydrotrimellitate) monoacetate, 1,2,3,4-butanetetracarboxylic acid dianhydride, 3,3′,4,4′-diphenylsulfonetetracarboxylic acid dianhydride, 3,3′,4,4′-benzophenonetetracarboxylic acid dianhydride, 3,3′,4,4′-biphenyltetracarboxylic acid dianhydride, 3,3′,4,4′-diphenyl ether tetracarboxylic acid dianhydride, 2,2-bis(3,4-anhydrodicarboxyphenyl)propane, 2,2-bis(3,4-anhydrodicarboxyphenyl)hexafluoropropane, 5-(2,5-dioxotetrahydro-3-furanyl)-3-methylcyclohexene-1,2-d icarboxylic acid anhydride, 3a,4,5,9b-tetrahydro-5-(tetrahydro-2,5-dioxo-3-furanyl)-naphtho[1,2-c]furane-1,3-d ione, 1,2,4,5-cyclohexanetetracarboxylic acid dianhydride, bicyclo-(2,2,2)-oct-7-ene-2,3,5,6-tetracarboxylic acid dianhydride, bicyclo[2.2.2]octane-2,3,5,6-tetracarboxylic acid dianhydride and the like.

Among the above specific examples, from the aspects of solvent solubility, adhesiveness to substrate and photosensitivity, 3,3′,4,4′-diphenylsulfonetetracarboxylic acid dianhydride, 3,3′,4,4′-benzophenonetetracarboxylic acid dianhydride, 3,3′,4,4′-biphenyltetracarboxylic acid dianhydride and 3,3′,4,4′-diphenyl ether tetracarboxylic acid dianhydride are preferred, and 3,3′,4,4′-diphenylsulfonetetracarboxylic acid dianhydride, 3,3′,4,4′-benzophenonetetracarboxylic acid dianhydride and 3,3′,4,4′-diphenyl ether tetracarboxylic acid dianhydride are more preferred, while 3,3′,4,4′-diphenyl ether tetracarboxylic acid dianhydride is particularly preferred.

These tetrabasic acid dianydride (a) may be used individually, or may also be used as mixtures of two or more species.

The aminophenol compound (b) used for the production of the phenolic hydroxy group-containing soluble polyimide resin (A) is not particularly limited as long as it is a compound having at least two amino groups and at least one phenolic hydroxy group in one molecule.

A preferred aminophenol compound (b) includes a compound having two amino groups and two phenolic hydroxy groups. A diaminodihydroxydiphenyl compound in which two phenyl groups each substituted with both an amino group and a hydroxy group, are bound directly or through a bridging group, is more preferred. The bridging group may be exemplified by —O—, —CO—, —SO₂—, —(CF₃)C(CF₃)—, a C1 to C3 alkylene group, a fluorene group, or the like, and among these, —O—, —SO₂— or —(CF₃)C(CF₃)—is preferred. As a more preferred aminophenol compound (b), a diaminodihydroxydiphenyl compound in which two phenyl groups each substituted with both an amino group and a hydroxy group are bound through —O—, —SO₂— or —(CF₃)C(CF₃)—, can be included.

Specific examples of the aminophenol compound (b) that can be used include 3,3′-diamino-4,4′-dihydroxydiphenylsulfone, 3,3′-diamino-4,4′-dihydroxydiphenyl ether, 3,3′-diamino-4,4′-dihydroxybiphenyl, 3,3′-dihydroxy-4,4′-diaminobiphenyl, 2,2-bis(3-amino-4-hydroxyphenyl)propane, 1,3-hexafluoro-2,2-bis(3-amino-4-hydroxyphenyl)propane, 9,9′-bis(3-amino-4-hydroxyphenyl)fluorene and the like, but are not limited to these.

Among the above-mentioned compounds, 3,3′-diamino-4,4′-dihydroxydiphenylsulfone, 3,3′-diamino-4,4′-dihydroxydiphenyl ether and 1,3-hexafluoro-2,2-bis(3-amino-4-hydroxyphenyl)propane are more preferred, and 3,3′-diamino-4,4′-dihydroxydiphenylsulfone is particularly preferred.

These aminophenol compounds (b) may be used individually, or may also be used as mixtures of two or more species.

As the diamino compound (c) used for the production of the phenolic hydroxy group-containing soluble polyimide resin (A), any compound having two amino groups in one molecule, except the compounds included in the above-described aminophenol compound (b), can all be used.

Preferred examples of the diamino compound (c) include a compound having two amino groups on one benzene ring, a diamino compound having two aminophenyl groups bound directly or through a bridging group, a silicone diamine, and the like. The bridging group may be included by —O—, —S—, —CO—, —SO—, —SO₂—, —O—C₆H₄—O—, —(CF₃)C(CF₃)—, a C₁-C₃ alkylene group, or the like, and among these, —O— and —O—C₆H₄—O— are preferred. As the more preferred diamino compound (c), a diamino compound having two aminophenyl groups bound through —O— or —O—C₆H₄—O—, can be mentioned.

Specific examples of the diamino compound (c) include m-phenylenediamine, p-phenylenediamine, m-tolylenediamine, 4,4′-diaminodiphenyl ether, 3,3′-dimethyl-4,4′-diaminodiphenyl ether, 3,4′-diaminodiphenyl ether, 4,4′-diaminodiphenylthio ether, 3,3′-dimethyl-4,4′-diaminodiphenylthio ether, 3,3′-diethoxy-4,4′-diaminodiphenylthio ether, 3,3′-diaminodiphenylthio ether, 4,4′-diaminobenzophenone, 3,3′-dimethyl-4,4′-diaminobenzophenone, 3,3′-diaminodiphenylmethane, 4,4′-diaminodiphenylmethane, 3,4′-diaminodiphenylmethane, 3,3′-dimethoxy-4,4′-diaminodiphenylthio ether, 2,2′-bis(3-aminophenyl)propane, 2,2′-bis(4-aminophenyl)propane, 4,4′-diaminodiphenylsulfoxide, 3,3′-diaminodiphenylsulfone, 4,4′-diaminodiphenylsulfone, 3,3′-diaminobiphenyl, p-xylylenediamine, m-xylylenediamine, o-xylylenediamine, 2,2′-bis(3-aminophenoxyphenyl)propane, 2,2′-bis(4-aminophenoxyphenyl)propane, 1,3-bis(4-aminophenoxyphenyl)benzene, 1,3-bis-(3-aminophenoxy)benzene, 1,3′-bis(3-aminophenoxyphenyl)propane, bis(4-amino-3-methylphenyl)methane, bis(4-amino-3,5-dimethylphenyl)methane, bis(4-amino-3-ethylphenyl)methane, bis(4-amino-3,5-diethylphenyl)methane, bis(4-amino-3-propylphenyl)methane, bis(4-amino-3,5-dipropylphenyl)methane, a silicone diamine, isophorone diamine, hexamethylenediamine, trimethylhexamethylenediamine, and the like, but the diamino compound (c) is not to be limited to these.

Among the above specific examples, 3,4′-diaminodiphenyl ether, 4,4′-diaminodiphenyl ether, 1,3-bis-(3-aminophenoxy)benzene and a silicone diamine, which exhibit excellent effects of adhesiveness to substrate, developability and flexibility, are preferred, and 3,4′-diaminodiphenyl ether and 1,3-bis-(3-aminophenoxy)benzene are more preferred, while 1,3-bis-(3-aminophenoxy)benzene is particularly preferred.

These diamino compounds (c) may be used individually, or may also be used as mixtures of two or more species.

It is preferable that the phenolic hydroxy group-containing soluble polyimide resin (A) used in the present invention is obtained from a combination of the above preferred tetrabasic acid dianhydride (a), the above preferred aminophenol compound (b) and the above preferred diamino compound (c).

That is, preferred is a phenolic hydroxy group-containing soluble polyimide resin (A) obtained from a combination in which the tetrabasic acid dianhydride (a) is a benzenetetracarboxylic acid dianhydride having two acid anhydride groups on one benzene ring, or an aromatic tetracarboxylic acid dianhydride in which two phenyl groups, which each has one acid anhydride group, are bound directly or through a bridging group selected from the group consisting of —O—, —CO— and —SO₂—, or are bound as a condensed ring; the aminophenol compound (b) is a diaminodihydroxydiphenyl compound in which two phenyl groups each substituted with both an amino group and a hydroxy group, are bound directly or through a bridging group selected from the group consisting of —O—, —CO—, —SO₂—, —(CF₃)C(CF₃)—, a C1-C3 alkylene group and a fluorene group, and more preferably from the group consisting of —O—, —SO₂— and —(CF₃)C(CF₃)—; and the diamino compound (c) is a compound having two amino groups on one benzene ring, or a diamino compound in which two aminophenyl groups are bound directly or through a bridging group selected from the group consisting of —O—, —S—, —CO—, —SO—, —SO₂—, —O—C₆H₄—O—, —(CF₃)C(CF₃)— and a C1-C3 alkylene group, and more preferably from the group consisting of —O— and —O—C₆H₄—O—, or a silicone diamine.

More preferred is a phenolic hydroxy group-containing soluble polyimide resin (A) obtained from a combination in which the tetrabasic acid dianhydride (a) is an aromatic tetracarboxylic acid dianhydride in which two phenyl groups each having one acid anhydride group are bound directly or through —O—, —CO— or —SO₂—; the aminophenol compound (b) is a diaminodihydroxydiphenyl compound in which two phenyl groups, which are each substituted with both an amino group and a hydroxy group, are bound through —O—, —SO₂— or —(CF₃)C(CF₃)—; and the diamino compound (c) is a diamino compound having two aminophenyl groups bound through —O— or —O—C₆H₄—O—.

More specifically, there may be mentioned a polyimide resin produced, as the tetrabasic acid dianhydride (a), using 3,3′,4,4′-diphenylsulfonetetracarboxylic acid dianhydride, 3,3′,4,4′-benzophenonetetracarboxylic acid dianhydride, 3,3′,4,4′-biphenyltetracarboxylic acid dianhydride or 3,3′,4,4′-diphenyl ether tetracarboxylic acid dianhydride, more preferably 3,3′,4,4′-diphenylsulfonetetracarboxylic acid dianhydride, 3,3′,4,4′-benzophenonetetracarboxylic acid dianhydride or 3,3′,4,4′-diphenyl ether tetracarboxylic acid dianhydride, and particularly preferably 3,3′,4,4′-diphenyl ether tetracarboxylic acid dianhydride; as the aminophenol compound (b), using 3,3′-diamino-4,4′-dihydroxydiphenylsulfone, 3,3′-diamino-4,4′-dihydroxydiphenyl ether, 3,3′-diamino-4,4′-dihydroxybiphenyl, 3,3′-dihydroxy-4,4′-diaminobiphenyl, 2,2-bis(3-amino-4-hydroxyphenyl)propane, 1,3-hexafluoro-2,2-bis(3-amino-4-hydroxyphenyl)propane or 9,9′-bis(3-amino-4-hydroxyphenyl)fluorene, more preferably 3,31-diamino-4,41-dihydroxydiphenylsulfone, 3,3′-diamino-4,4′-dihydroxydiphenyl ether or 1,3-hexafluoro-2,2-bis(3-amino-4-hydroxyphenyl)propane, and particularly preferably 3,3′-diamino-4,4′-dihydroxydiphenyl sulfone; and as the diamino compound (c), using 3,4′-diaminodiphenyl ether, 4,4′-diaminodiphenyl ether, 1,3-bis-(3-aminophenoxy)benzene or a silicone diamine, more preferably 3,4′-diaminodiphenyl ether or 1,3-bis-(3-aminophenoxy)benzene, and particularly preferably 1,3-bis-(3-aminophenoxy)benzene.

The phenolic hydroxy group-containing soluble polyimide resin (A) can be obtained by subjecting a tetrabasic acid dianhydride (a), an aminophenol compound (b) and a diamino compound (c) to a polycondensation reaction in the presence of a catalyst generated by an equilibrium reaction of lactone and a base. At this time, it is more effective to use toluene, xylene or the like in combination as a dehydrating agent, in order to allow the reaction to proceed. According to this production method, a straight-chained aromatic polyimide copolymer can be easily produced without protecting the phenolic hydroxy group which is a functional group, and without causing a reaction between the phenolic hydroxy group and another reactive group, for example, the acid anhydride group or the amino group. The block copolymer as disclosed in Patent Document 3 may also be used, but it is preferable from the viewpoint of convenience in synthesis, that the copolymer is not a block copolymer. Therefore, in the present invention, the above desired polyimide can be typically synthesized by a single stage reaction.

In the present reaction, it is preferable to use the tetrabasic acid dianhydride (a) and the diamine components (the aminophenol compound (b) and the diamino compound (c)) at the use ratios as set in the above-mentioned range. To obtain a high molecular weight resin, it is preferable to use theoretical equivalents, or any one component in small excess of 10% by mole or less, and preferably 5% by mole or less. As for the polyimide resin being used in the present invention, any of those synthesized as described above can be used, but preferably, a polyimide resin having amino groups at both terminals, which is obtained using a small excess (an excess of about 0.1 to 5% by mole) of the diamine components, is preferred. Also, the use ratio (mole ratio) of the aminophenol compound (b) and the diamino compound (c) is such that preferably about 0.1 to 3 moles, and more preferably approximately 0.5 to 1.5 moles, of the diamino compound (c) is used relative to 1 mole of the aminophenol compound (b). The most preferred case is that the two compounds are used in equal moles.

When the compounds are used in these ratios, the ratios of various components in the polyimide resin are determined in accordance with the use ratios of these compounds.

The lactone used as the above catalyst is preferably γ-valerolactone, and the base used as the above catalyst is preferably pyridine or N-methylmorpholine.

Examples of the solvent used during the synthesis of the phenolic hydroxy group-containing soluble polyimide resin (A) include methyl ethyl ketone, methyl propyl ketone, methyl isopropyl ketone, methyl butyl ketone, methyl isobutyl ketone, methyl n-hexyl ketone, diethyl ketone, diisopropyl ketone, diisobutyl ketone, cyclopentanone, cyclohexanone, methylcyclohexanone, acetylacetone, γ-butyrolactone, diacetone alcohol, cyclohexen-1-one, dipropyl ether, diisopropyl ether, dibutyl ether, tetrahydrofuran, tetrahydropyrane, ethyl isoamyl ether, ethyl-t-butyl ether, ethyl benzyl ether, cresyl methyl ether, anisole, phenetole, methyl acetate, ethyl acetate, propyl acetate, isopropyl acetate, butyl acetate, isobutyl acetate, amyl acetate, isoamyl acetate, 2-ethylhexyl acetate, cyclohexyl acetate, methylcyclohexyl acetate, benzyl acetate, methyl acetoacetate, ethyl acetoacetate, methyl propionate, ethyl propionate, butyl propionate, benzyl propionate, methyl butyrate, ethyl butyrate, isopropyl butyrate, butyl butyrate, isoamyl butyrate, methyl lactate, ethyl lactate, butyl lactate, ethyl isovalerate, isoamyl isovalerate, diethyl oxalate, dibutyl oxalate, methyl benzoate, ethyl benzoate, propyl benzoate, methyl salicylate, N-methylpyrrolidone, N,N-dimethylformamide, N,N-dimethyl acetamide, dimethyl sulfoxide and the like, but are not limited to these. These solvents may be used individually or as mixtures of two or more species. As for the solvent in this case, a solvent dissolving the soluble polyimide resin (A) generated by the reaction is preferred, and a ketone-based solvent such as γ-butyrolactone is preferred, while a cyclic ketone having a 4- to 5-membered ring is more preferred.

Hereinafter, the method for producing the phenolic hydroxy group-containing soluble polyimide resin (A) will be described in more detail.

First, in an inert atmosphere of nitrogen or the like, the diamine components (aminophenol compound (b) and diamino compound (c)), the tetrabasic acid dianhydride (a), and if necessary, a dehydrating agent for removing the water generated from the reaction are appropriately added to any of the above-described solvents, which has been mixed with lactone and a base as catalysts. Subsequently, the reaction is sufficiently performed with heating and stirring, while distilling off the water generated when an imide ring is formed, and thus a phenolic hydroxy group-containing soluble polyimide resin (A) solution is obtained. The dehydrating agent in this case may be exemplified by toluene, xylene or the like. Typically, the reaction temperature is preferably 120 to 230° C. The reaction time is greatly affected by the desired degree of polymerization of the polyimide, and the reaction temperature. Typically, it is preferable to continue the reaction under the conditions established in accordance with the desired degree of polymerization of the polyimide (for example, the use ratios of the tetrabasic acid dianhydride (a) and the diamine components, reaction temperature and the like), until the viscosity increase according to the progress of the reaction reaches equilibrium, and the maximum molecular weight is obtained. The reaction time is usually several minutes to about 20 hours. Furthermore, after the generated polymer is separated by introducing the obtained solution into a poor solvent such as methanol or hexane, and then purified according to a reprecipitation method to eliminate side products, a phenolic hydroxy group-containing soluble polyimide resin (A) of higher purity can be obtained.

The weight average molecular weight of the soluble polyimide resin (A) obtained as described above is preferably about 20,000 to 400,000, and more preferably about 30,000 to 200,000, while the number average molecular weight is preferably about 5,000 to 50,000, and more preferably 10,000 to 30,000. The hydroxy group equivalent is 200 to 5000 g/eq, preferably 300 to 1000 g/eq, preferably 350 to 900 g/eq, more preferably 350 to 800 g/eq, even more preferably 350 to 700 g/eq, and most preferably 400 to 600 g/eq. In addition, the weight average molecular weight and the number average molecular weight are numerical values determined by gel permeation chromatography with polystyrene standards (the same hereinafter).

Next, the positive type photosensitive polyimide resin composition of the present invention will be explained.

The resin composition is a composition comprising the above-described phenolic hydroxy group-containing soluble polyimide resin (A), diazo-based positive type photosensitizer (B) and epoxy resin (C).

The content proportion of the soluble polyimide resin (A) in the positive type photosensitive polyimide resin composition of the present invention is usually 20 to 95% by weight, preferably 40 to 95% by weight, more preferably 50 to 95% by weight, and even more preferably 60 to 90% by weight, based on 100% by weight of the solid content of the positive type photosensitive polyimide resin composition.

The diazo-based positive type photosensitizer (B) used in the positive type photosensitive polyimide resin composition of the present invention is not particularly limited as long as it is a photosensitizer having a diazido group, such as an ester of a diazoquinonesulfonic acid compound (quinonediazidosulfonic acid compound), which is capable of generating acid by light, and is used in positive type development. For example, an ester of a sulfonic acid-substituted diazidoquinone compound with a hydroxy compound, and preferably an ester of a diazoquinonesulfonic acid compound with a hydroxy compound (preferably a phenol compound) can be mentioned. The ester may be exemplified by a diazobenzoquinonesulfonyl ester, a diazonaphthoquinonesulfonyl ester or the like, and a diazonaphthoquinonesulfonyl ester is more preferred.

Examples of the ester of diazoquinonesulfonic acid include 1,2-benzoquinonediazido-4-sulfonic acid ester, 1,2-naphthoquinone-2-diazido-5-sulfonic acid ester, 1,2-naphthoquinone-2-diazido-4-sulfonic acid ester, 1,2-naphthoquinone-2-diazido-5-sulfonic acid ester-ortho-cresol ester, 1,2-naphtoquinone-2-diazido-5-sulfonic acid ester-para-cresol ester, and the like. As the esterification component for the above-mentioned esters (hydroxy compound), phenol compounds are preferred, and for example, 2,4-dihydroxybenzophenone, 2,3,4-trihydroxybenzophenone, 2,3,4,4′-tetrahydroxybenzophenone, 2,2′,3,4,4′-pentahydroxybenzophenone, phenol, 1,3-dihydroxybenzene, 1,3,5-trihydroxybenzene, bisphenol A, bisphenol F, bisphenol S, novolac resins, methyl gallate, ethyl gallate, phenyl gallate and the like.

As for the amount of addition of the diazo-based positive type photosensitizer (B), it is preferable to be mixed in an amount of usually 5 to 30% by weight, and preferably 10 to 20% by weight, based on the soluble polyimide resin (A).

The epoxy resin (C) used in the positive type photosensitive polyimide resin composition of the present invention is added for the purpose of reacting with the phenolic hydroxy group and the terminal acid anhydride group or/and terminal amino group in the phenolic hydroxy group-containing soluble polyimide resin (A) after alkali development. After patterning, when the epoxy resin (C) is reacted with the reactive substituents of the soluble polyimide resin (A), the cross-linking density of the polyimide resin of the present invention increases, the resistance to polar solvent is enhanced, and at the same time, adhesiveness to substrate and heat resistance are enhanced. The reaction temperature at that time is preferably 150 to 250° C.

The epoxy resin (C) is not particularly limited, if it has two or more epoxy groups in one molecule, but from the aspects of mechanical strength, flame retardancy and the like, an epoxy resin having an aromatic ring such as a benzene ring, a biphenyl ring or a naphthalene ring, is preferred. Specifically, a novolac type epoxy resin, a xylylene skeleton-containing epoxy resin, a biphenyl skeleton-containing epoxy resin, a bisphenol A type epoxy resin, a bisphenol F type epoxy resin, a triphenylmethane type epoxy resin, and a glyoxal type epoxy resin may be mentioned, but from the viewpoint of compatibility with the phenolic hydroxy group-containing soluble polyimide resin (A), a biphenyl skeleton-containing epoxy resin is particularly preferred.

Furthermore, the epoxy equivalent is not particularly limited as long as the effects of the present invention can be exhibited. The epoxy equivalent cannot be limited to a specific value since the value may vary widely depending on the kind of the epoxy resin, but is usually 1,000 g/eq or less, preferably 600 g/eq or less, more preferably 500 g/eq or less, most preferably 400 g/eq or less, and usually 100 g/eq or more, preferably 150 g/eq or more, and more preferably 200 g/eq or more. Preferably, the epoxy equivalent is in the range of 150 to 500 g/eq.

The biphenyl skeleton-containing epoxy resin is preferably an epoxy resin represented by the following formula (1):

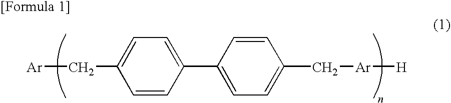

wherein n represents an average value of a repeating number from 1 to 10; Ar is a monovalent or divalent residue of a compound represented by the following formula (2) or formula (3) (a monovalent or divalent residue obtained by taking one or two hydrogen atoms from the ring of a phenyl group or a naphthyl group), and Ar on the left terminal is monovalent, while Ar in the parentheses is divalent. In the case where Ar is a residue of a compound of formula (2), its binding position is not particularly limited, but is preferably the ortho position or/and para position from the position of the ether bond (when Ar is monovalent, binding at one site of the ortho position or the para position, and when Ar is divalent, binding at two sites selected from two ortho positions and the para positions).

In the case of a residue of a naphthol compound of formula (3), the position of the glycidyl ether group on the naphthalene ring is not particularly limited, but is typically the 1-position (referred to as α-naphthol type) or the 2-position (referred to as β-naphthol type) of the naphthalene ring. Since the binding position of the naphthalene ring in the formula (1) is different depending on the position and number of another substituent (R), no conclusion can be made, but in the case where R is a hydrogen atom, the binding position is the 2-position or/and the 4-position in the α-naphthol type (when Ar is monovalent, binding at one site of the 2-position or 4-position, and when Ar is divalent, binding at two sites of the 2-position and 4-position). In the β-naphthol type, the binding position is the 1-position or/and the 3-position (when Ar is monovalent, binding at one site of the 1-position or 3-position, and when Ar is divalent, binding at two sites of the 1-position and 3-position). In the case where R is a group other than a hydrogen atom, when there is a substituent at the above-mentioned position, binding occurs at any of the remaining positions. In the case of the naphthalene ring of the formula (3), it is more preferable that R is a hydrogen atom.

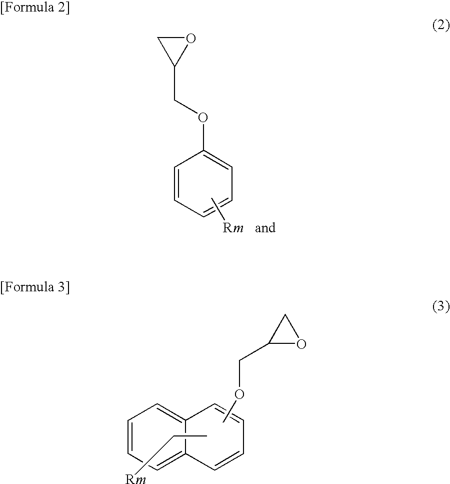

wherein m represents the number of substituent R, and is an integer from 1 to 3; R each represents any of a hydrogen atom, a halogen atom, a hydrocarbon group having 1 to 15 carbon atoms, a trifluoromethyl group, an allyl group and an aryl group, and individual Rs may be identical with or different from each other. In addition, the “number of substituent R” means the number of R when R represents an atom other than a hydrogen atom, or a substituent.

Furthermore, Ars may be identical or different, and when Ars are different, the groups of formula (2) and formula (3) are to be arranged in an arbitrary order.

Preferably, in the biphenyl skeleton-containing epoxy resin represented by the formula (1), Ar may be any of the residues of the compounds of formula (2) and (3), but usually, the resin in which all of Ars in the formula (1) are the same compound residues, and is unsubstituted (R═H), or the resin in which m is 1, and R is a halogen atom, a lower alkyl group having 1 to 3 carbon atoms or a trifluoromethyl group, are preferred. It is more preferable when Ar is the residue of a compound of formula (2), and most preferable is unsubstituted. Also, n is preferably about 3 to 8.

As specific examples thereof, there may be mentioned NC-3000H (trade name, Nippon Kayaku Co., Ltd., corresponding to a resin of formula (1), wherein Ar is formula (2), and R is a hydrogen atom), and the like.

As for the amount of addition of the epoxy resin (C), it is preferable to add an amount such as that the epoxy group in the epoxy resin (C) is in the range of 0.1 to 1.5 equivalents based on the sum of the phenolic hydroxy group of the phenolic hydroxy group-containing soluble polyimide resin (A) and the terminal acid anhydride group or/and terminal amino group. Furthermore, the amount of the phenolic hydroxy group and the acid anhydride group or amino group in the phenolic hydroxy group-containing polyimide resin (A) can be calculated from the mole number of the tetrabasic acid dianhydride (a), the aminophenol compound (b) and the diamino compound (c) used in the synthesis of the phenolic hydroxy group-containing soluble polyimide resin (A), and the number of the acid anhydride structures, the number of amino groups and the number of phenolic hydroxy groups in one molecule.

The weight ratio of the phenolic hydroxy group-containing soluble polyimide resin (A) and the epoxy resin (C) in the positive type photosensitive polyimide resin composition of the present invention cannot be mentioned specifically since the weight ratio may vary depending on the active hydrogen equivalent of the compound used or the epoxy equivalent. However, in general, the weight ratio is in the range of 15 to 200 parts by weight, preferably 20 to 100 parts by weight, more preferably 30 to 100 parts by weight, and even more preferably 40 to 90 parts by weight, of the epoxy resin (C) based on 100 parts by weight of the soluble polyimide resin (A) (solid content).

The positive type photosensitive polyimide resin composition of the present invention can be further added a thermosetting catalyst as necessary, for the purpose of accelerating the thermal curing reaction of the phenolic hydroxy group-containing soluble polyimide resin (A) with the epoxy resin (C). Examples of the thermosetting catalyst include imidazoles such as 2-methylimidazole, 2-ethylimidazole, 2-ethyl-4-methylimidazole, 2-phenyl-4,5-dihydroxymethylimidazole and 2-phenyl-4-methyl-5-hydroxymethylimidazole; tertiary amines such as 2-(dimethylaminomethyl)phenol and 1,8-diaza-bicyclo(5,4,0)undecene-7; phosphines such as triphenylphosphine; metal compounds such as tin octoate; and the like. Preferred thermosetting catalyst includes imidazoles. The amount of addition of the thermosetting catalyst is 0 to 10%, preferably 0.1 to 10%, more preferably 0.2 to 5%, even more preferably 0.2 to 2%, and still more preferably 0.2 to 1%, based on the amount of addition of the epoxy resin (C).

The positive type photosensitive polyimide resin composition of the present invention preferably includes a solvent dissolving the polyimide (polyimide dissolving solvent), for convenience when using. As for the solvent, those polyimide dissolving solvents mentioned as the solvent used during synthesis are preferred, and cyclic ketones having 4- to 5-membered rings such as γ-butyrolactone are preferred. When the polyimide resin composition is a resin solution containing a solvent, the solids content relative to the entirety of the above resin solution is about 10 to 65% by weight, more preferably 20 to 50% by weight, and even more preferably 25 to 50% by weight. The resin solution can be used for the formation of films or layers comprising the positive type photosensitive polyimide resin composition of the present invention. The formation of films or layers can be carried out by applying the resin solution on a flat smooth substrate, or the like.

The positive type photosensitive polyimide resin composition of the present invention can further contain, if necessary, a filler such as talc, barium sulfate, calcium carbonate, magnesium carbonate, barium titanate, aluminum hydroxide, aluminum oxide, silica or clay; a thixotropic agent such as Aerosil; a colorant such as phthalocyanine blue, phthalocyanine green or titanium oxide; silicone; a fluorine-based leveling agent; a defoaming agent and the like. These agents are used in an amount occupying 0 to 50% by weight of the positive type photosensitive polyimide resin composition (solid content) of the present invention.

The positive type photosensitive polyimide resin composition of the present invention can also be used as a dry film resist having a structure in which the resin composition is sandwiched between a supporting film and a protective film.

The positive type photosensitive polyimide resin composition (liquid or film-like) of the present invention is useful as an interlayer insulating material in electronic elements, or as a resist material for solder resist, coverlay and the like for optical waveguides connecting optical elements or for printed boards, and in addition, can also be used in color filters, printing inks, oriented films, sealants, paints, coating agents, adhesives and the like.

The cured product of the positive type photosensitive polyimide resin composition of the present invention is used in, for example, electric/electronic elements such as resist films and interlayer insulating materials for the buildup technique. Specific applications thereof include computers, home electric appliances, mobile instruments and the like. The film thickness of this cured product layer is about 1 to 160 μm, and preferably about 5 to 100 μm.

A substrate having a cured product layer of the positive type photosensitive polyimide resin composition of the present invention can be obtained, for example, as follows. That is, in the case of using a liquid state resin composition, a coating film can be formed by applying the composition of the present invention on a substrate by a method such as a screen printing method, a spraying method, a roll coating method, an electrostatic coating method or a curtain coating method, such that the film thickness after drying becomes 1 to 160 μm, and drying the coating film typically at a temperature of 50 to 110° C., and preferably 60 to 100° C. Then, the coating film is irradiated directly or indirectly through a photomask on which an exposure pattern has been formed, with an active energy ray at an intensity of typically 10 to 2,000 mJ/cm², and then is developed using the developer solution that will be described later, for example, by spraying, oscillating immersion, brushing, scrubbing or the like. Subsequently, if necessary, by further irradiating the coating film with ultraviolet rays, and conducting the heat treatment typically at a temperature of 100 to 250° C., preferably 140 to 220° C., a substrate having a cured film of polyimide resin composition which has excellent flame retardancy, and satisfies various properties such as heat resistance, solvent resistance, acid resistance, adhesiveness and flexibility, is obtained.

The above active energy ray may be exemplified by ultraviolet rays, visible rays, infrared rays, electron beams, radioactive rays or the like, but upon considering the use application, ultraviolet rays or electron beams are most preferred.

As the above-described aqueous alkaline solution used in development, an aqueous solution of inorganic alkalis such as potassium hydroxide, sodium hydroxide, sodium carbonate, potassium carbonate, sodium hydrogen carbonate, potassium hydrogen carbonate, sodium phosphate and potassium phosphate, or an aqueous solution of organic alkalis such as tetramethylammonium hydroxide, tetraethylammonium hydroxide, tetrabutylammonium hydroxide, monoethanolamine, diethanolamine and triethanolamine, can be used.

### EXAMPLES

Hereinafter, the present invention will be described in more detail by way of Examples, but the present invention is not to be limited to the following Examples.

### Synthesis Example 1

### Synthesis of Phenolic Hydroxy Group-Containing Soluble Polyimide Resin (A)

A 500 mL flask equipped with a stirring apparatus, a reflux tube, a water trap and a thermometer, was purged with nitrogen gas, and then 148.41 g of γ-butyrolactone as a solvent, 0.82 g of γ-valerolactone and 1.30 g of pyridine as catalysts, 25.48 g of ODPA (3,3′,4,4′-diphenyl ether tetracarboxylic acid dianhydride, manufactured by Manac, Inc., molecular weight 310.22) as the tetrabasic acid dianhydride (a), 11.74 g of ABPS (3,3′-diamino-4,4′-dihydroxydiphenylsulfone, manufactured by Nippon Kayaku Co., Ltd., molecular weight 280.30) as the aminophenol compound (b), 12.25 g of APB-N (1,3-bis-(3-aminophenoxy)benzene, manufactured by Mitsui Chemicals, Inc., molecular weight 292.34) as the diamino compound (c), and 28.00 g of toluene as a dehydrating agent were introduced into the flask. The contents of the flask were stirred at 180° C. for 8 hours, while removing the water generated from the reaction, and a resin solution containing 24% by weight of a polyimide resin having a phenolic hydroxy group was obtained (this solution is referred to as A-1). The hydroxy group equivalent (solid content) of the obtained polyimide resin was 555.2 g/eq, and the number average molecular weight was 21,800 and the weight average molecular weight was 107,400 calculated on the basis of styrene standards.

### Synthesis Example 2

### Synthesis of Phenolic Hydroxy Group-Containing Soluble Polyimide Resin (A)

A 500 mL flask equipped with a stirring apparatus, a reflux tube, a water trap and a thermometer was purged with nitrogen gas, and 148.25 g of γ-butyrolactone as a solvent, 0.90 g of γ-valerolactone and 1.43 g of pyridine as catalysts, 29.10 g of BTDA (3,3′,4,4′-benzophenonetetracarboxylic acid dianhydride, manufactured by Daicel Chemical Industries, Ltd., molecular weight 322.23) as the tetrabasic acid dianhydride (a), 10.91 g of ADPE (3,3′-diamino-4,4′-dihydroxydiphenyl ether, Nippon Kayaku Co., Ltd., molecular weight 232.24) as the aminophenol compound (b), 9.41 g of 3,4′-ODA (3,4′-diaminodiphenyl ether, manufactured by JFE Chemical Corp., molecular weight 200.24) as the diamino compound (c), and 28.00 g of toluene as a dehydrating agent were introduced into the flask. The contents of the flask were stirred at 180° C. for 8 hours, while removing the water generated from the reaction, and a resin solution containing 24% by weight of a polyimide resin having a phenolic hydroxy group was obtained. The hydroxy group equivalent (solid content) of the obtained polyimide resin was 491.5 g/eq, and the number average molecular weight was 16,200 and the weight average molecular weight was 59,200 calculated on the basis of styrene standards.

### Example 1

The resin solution (A-1) obtained in the above Synthesis Example 1, NC-3000H manufactured by Nippon Kayaku Co., Ltd. (biphenyl skeleton-containing epoxy resin, epoxy equivalent 290 g/eq, softening point 70° C., Ar in the formula (1) is corresponding to formula (2)) as an epoxy resin, 1,2-naphthoquinone-2-diazido-5-sulfonic acid ester (ester component: 2,3,4-trihydroxybenzophenone) as a diazido-based positive type photosensitizer, and 2-phenyl-4,5-dihydroxymethylimidazole (2PHZ) as a curing accelerator were mixed at the composition ratios indicated in Table 1 (units are in “parts by weight”; hereinafter, the same unless stated otherwise), to thus obtain the positive type photosensitive polyimide resin composition of the present invention.

### Comparative Example 1

To the polyimide resin solution synthesized according to Example 2-1 of Patent Document 3 (solids concentration 20%, this solution is referred to as R-1), 1,2-naphthoquinone-2-diazido-5-sulfonic acid ester as a diazido-based positive type photosensitizer was mixed at the composition ratio indicated in Table 1 to obtain a positive type photosensitive polyimide resin composition for comparison.

(Note): Polyimide resin synthesized according to Example 2-1 of Patent Document 3:

A block copolymer type polyimide resin obtained by allowing:

(a) Bicyclo(2,2,2)-oct-7-ene-2,3,5,6-tetracarboxylic acid dianhydride (BCD) (60 millimoles) and

(b) 4,4′-Diaminodiphenyl ether (p-DADE) (30 millimoles), to react, and then allowing:

(c) 3,4′-diaminodiphenyl ether (m-DADE) (30 millimoles),

(d) 2,2-bis[4-(4-aminophenoxy)phenyl]hexafluoropropane (HOCF3AB) (30 millimoles) and

(e) 3,3′,4,4′-biphenyltetracarboxylic acid dianhydride (BPDA) (30 millimoles), to react.

TABLE 1

| | | Comparative |
|---|---|---|
| | Example 1 | Example 1 |
| A-1 | 100.00 | |
| R-1 | | 100.00 |
| 1,2-Naphthoquinone-2-diazido- | 3.60 | 3.00 |
| 5-sulfonic acid ester | | |
| NC-3000H | 12.54 | |
| 2 PHZ | 0.38 | |

(I) Formation of Dry Coating Film on Printed Board, Development and Curing, and Evaluation Thereof

The positive type photosensitive polyimide resin composition described above was applied on a printed board by a screen printing method such that the film thickness upon drying would become 20 μm, and the coating film was dried in a hot air dryer at 80° C. for 30 minutes, to obtain a dry resin film having a film thickness of 20 μm the board. The following evaluation tests were performed using said dry resin film.

(1) Tackiness

Tackiness of the obtained dry resin film was evaluated by the below-described method. The evaluation results are presented in Table 2.

(2) Developability and Resolution Property

Next, a 50 μm-thick negative pattern was adhered to the above-obtained dry resin film on the board, and then irradiated with ultraviolet rays using an ultraviolet exposure apparatus (ORC Manufacturing Co., Ltd., Model HMW-680GW) at a cumulative dose of 500 mJ/cm². After the irradiation, spray development was performed with a 3% aqueous solution of sodium hydroxide for 120 seconds, at a spray pressure of 2.0 kg/cm², and washing with water was carried out to remove the resin at the ultraviolet irradiated parts. For the transferred pattern of the resin film obtained after the development, developability and resolution property were evaluated by the following methods. The evaluation results are presented in Table 2.

(3) Adhesiveness, Solvent Resistance, Acid Resistance, Heat Resistance, PCT Resistance and Thermal Impact Resistance

The above-described resin film after the development was heated in a hot air dryer at 150° C. for 60 minutes to cure, and using the obtained cured resin film, the aforementioned items were respectively evaluated by the following methods. The evaluation results are presented in Table 2.

(II) Evaluation of Board Bending and Flexibility of Polyimide Film Substrate

A cured resin film was formed on a polyimide film by the same method as in the above (I), except that the printed board in the above (I) was changed to a polyimide film having a thickness of 25 μm, and the bending (board bending) and flexibility of the obtained film were evaluated by the following methods. The evaluation results are presented in Table 2.

(III) Evaluation of Flame Retardancy of Cured Resin Film

A cured resin film was formed by the same method as in the above (I), except that the printed board in the above (I) was changed to a PET film, and only the cured resin film was peeled off from the PET film on the board. The flame retardancy of the obtained cured resin film was evaluated by the following method. The evaluation results are presented in Table 2.

The testing methods and the evaluation methods in the above (I) to (III) are as follows.

(i) Tackiness

Absorbent cotton was rubbed against the dried resin film coated on a printed board, and the tackiness was evaluated on the basis of the following criteria.

◯: The absorbent cotton does not stick.

x: Lint of the absorbent cotton adheres to the film.

(ii) Developability

The external appearance of the transferred pattern of the resin film obtained after the development and water washing, was visually observed, and the developability was evaluated on the basis of the following criteria.

◯: The resin composition at the exposed parts is completely removed by the development.

x: There is some resin composition unremoved even after the development and remaining behind, at the exposed parts.

(iii) Resolution Property

The external appearance of the transferred pattern of the resin film obtained after the development and water washing was observed under a microscope, and the resolution property was evaluated on the basis of the following criteria.

◯: There is no peeling at the unexposed parts, and linear pattern edges are reproduced.

x: Peeling occurs at the unexposed parts, or the pattern edges are undulating.

(iv) Adhesiveness

According to JIS K5400, one-hundred cross-cut squares having a size of 1 mm for each edge were made on the cured resin film on the board, and then a peeling test was performed using a cellophane tape, to evaluate the adhesiveness on the basis of the following criteria.

◯: No peeling.

Δ: Peeling does not occur, but the edges of the cross-cut squares become rough.

x: 1/100 or more squares are peeled.

(v) Solvent Resistance

The cured resin film on the printed board was immersed in N-methylpyrrolidone at room temperature for 30 minutes. After taking out the film, it was checked whether the external appearance had any defect, and then a peeling test was performed using a cellophane tape, to evaluate the solvent resistance on the basis of the following criteria.

◯: No defect is seen at the surface, and no swelling or no peeling occurs.

Δ: The surface becomes rough, but no swelling or no peeling occurs.

x: Swelling or peeling occurs.

(vi) Acid Resistance

The cured resin film on the printed board was immersed in a 10% aqueous hydrochloric acid solution at room temperature for 30 minutes. After taking out the film, it was checked whether the external appearance had any defect, and then a peeling test was performed using cellophane tape, to evaluate the acid resistance on the basis of the following criteria.

◯: No defect is seen at the surface, and no swelling or no peeling occurs.

x: Swelling or peeling occurs.

(vii) Heat Resistance

The cured resin film on the printed board was coated with a rosin-based flux, and then immersed in a solder bath at 270° C. 3 times for 10 seconds each. After natural cooling to room temperature, and then a peeling test was performed using cellophane tape, to evaluate the heat resistance on the basis of the following criteria.

◯: No defect is seen at the surface, and no swelling or no peeling occurs.

x: Swelling or peeling occurs.

(viii) PCT Resistance

The cured resin film on the board was immersed in hot water at 121° C. and at 2 atmospheres for 96 hours. After taking out the film, it was checked whether the external appearance had any defect, and then a peeling test was performed using a cellophane tape, to evaluate the PCT resistance on the basis of the following criteria (PCT: Pressure Cooker Test).

◯: No defect is seen at the surface, and no swelling or no peeling occurs.

x: Swelling or peeling occurs.

(viii) Thermal Impact Resistance

The cured resin film on the board was subjected to a thermal history of 1000 cycles, each cycle consisting of 30 minutes at −55° C. and 30 minutes at 125° C., and then the surface external appearance was observed with a microscope to evaluate the thermal impact resistance on the basis of the following criteria.

◯: No crack is generated on the surface.

x: Cracks have been generated on the surface.

(ix) Board Bending

The external appearance of the polyimide film having the cured resin film coated thereon, was visually observed, and the board bending was evaluated on the basis of the following criteria.

◯: Film bending is not observed.

Δ: Negligible bending is observed in the film.

x: Film bending is observed.

(x) Flexibility

The polyimide film having the cured resin film was folded to 180 degree angle, and the external appearance was visually observed, to evaluate the flexibility on the basis of the following criteria.

◯: No crack is observed on the cured resin film.

x: Cracks have been generated on the cured resin film.

(xi) Flame Retardancy

The cured resin film peeled off from the PET film was cut into strips each having a width of 1 cm, and then the behavior when burner flame was brought near, was observed to evaluate the flame retardancy on the basis of the following criteria.

◯: Does not combust, or extinguished instantaneously when separated from the burner.

x: Keeps combusting for a while even though separated from the burner.

TABLE 2

| | | Comparative |
|---|---|---|
| | Example 1 | Example 1 |
| Tackiness | ◯ | ◯ |
| Developability | ◯ | X |
| Resolution property | ◯ | X |
| Adhesiveness | ◯ | Δ |
| Solvent resistance | ◯ | Δ |
| Acid resistance | ◯ | ◯ |
| Heat resistance | ◯ | X |
| PCT resistance | ◯ | ◯ |
| Thermal impact resistance | ◯ | ◯ |
| Board bending | Δ | Δ |
| Flexibility | ◯ | ◯ |
| Flame retardancy | ◯ | ◯ |

As understood from the above results, it is clear that the cured product of the positive type photosensitive polyimide

resin composition of the present invention allows easy patterning,

and has excellent adhesiveness to substrate, flame retardancy and heat resistance, as well as sufficient flexibility.

1. A positive type photosensitive polyimide resin composition comprising a phenolic hydroxy group-containing soluble polyimide resin (A) obtained by subjecting a tetrabasic acid dianhydride (a), an aminophenol compound having at least two amino groups and at least one phenolic hydroxy group in one molecule (b) (hereinafter, also simply referred to as an aminophenol compound (b)), and a diamino compound (c) to a polycondensation reaction; a diazo-based positive type photosensitizer (B); and an epoxy resin (C).

2. The positive type photosensitive polyimide resin composition according to claim 1, wherein the tetrabasic acid dianhydride (a) is one or more selected from the group consisting of 3,3′,4,4′-diphenylsulfonetetracarboxylic acid dianhydride, 3,3′,4,4′-benzophenonetetracarboxylic acid dianhydride, 3,3′,4,41-biphenyltetracarboxylic acid dianhydride and 3,3′,4,4′-diphenyl ether tetracarboxylic acid dianhydride.

3. The positive type photosensitive polyimide resin composition according to claim 1, wherein the aminophenol compound (b) is one or more selected from the group consisting of 3,3′-diamino-4,4′-dihydroxydiphenylsulfone, 3,3′-diamino-4,4′-dihydroxydiphenyl ether, 3,3′-diamino-4,4′-dihydroxybiphenyl, 3,3′-dihydroxy-4,4′-diaminobiphenyl, 2,2-bis(3-amino-4-hydroxyphenyl)propane, 1,3-hexafluoro-2,2-bis(3-amino-4-hydroxyphenyl)propane and 9,9′-bis(3-amino-4-hydroxyphenyl)fluorene.

4. The positive type photosensitive polyimide resin composition according to claim 1, wherein the diamino compound (c) is one or more selected from the group consisting of 3,4′-diaminodiphenyl ether, 4,4′-diaminodiphenyl ether, 1,3-bis-(3-aminophenoxy)benzene and a silicone diamine.

5. The positive type photosensitive polyimide resin composition according to any one of claims 1 to 4, wherein the hydroxy group equivalent of the phenolic hydroxy group-containing soluble polyimide resin (A) is 200 to 5,000 g/eq.

6. The positive type photosensitive polyimide resin composition according to any one of claims 1 to 4, wherein the epoxy resin (C) is an epoxy resin having a biphenyl skeleton.

7. The positive type photosensitive polyimide resin composition according to claim 6, wherein the epoxy resin (C) having a biphenyl skeleton has the following formula (1): 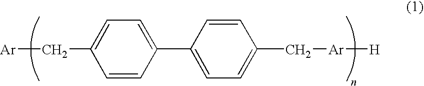
wherein n represents an average value of a repeating number from 1 to 10; Ar is a monovalent or divalent group represented by the following formula (2) or the following formula (3): 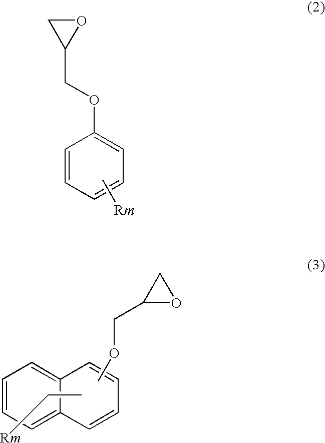
m represents an integer from 1 to 3 and represents the number of substituent R; R each represents any of a hydrogen atom, a halogen atom, a hydrocarbon group having 1 to 15 carbon atoms, a trifluoromethyl group, an allyl group and an aryl group, and individual Rs may be identical with or different from each other; and Ars may be identical or different, and when Ars are different, the groups of formulas (2) and (3) are arranged in an arbitrary order.

8. A cured product obtained by curing the positive type photosensitive polyimide resin composition according to any one of claims 1 to 4.

9. A substrate having a layer of the cured product according to claim 8.

10. The positive type photosensitive polyimide resin composition according to claim 1, wherein the tetrabasic acid dianhydride (a) is one or more selected from the group consisting of 3,3′,4,4′-diphenylsulfonetetracarboxylic acid dianhydride, 3,3′,4,4′-benzophenonetetracarboxylic acid dianhydride, 3,3′,4,4′-biphenyltetracarboxylic acid dianhydride and 3,3′,4,4′-diphenyl ether tetracarboxylic acid dianhydride; the aminophenol compound (b) is one or more selected from the group consisting of 3,3′-diamino-4,4′-dihydroxydiphenylsulfone, 3,3′-diamino-4,4′-dihydroxydiphenyl ether, 3,3′-diamino-4,4′-dihydroxybiphenyl, 3,3′-dihydroxy-4,4′-diaminobiphenyl, 2,2-bis(3-amino-4-hydroxyphenyl)propane, 1,3-hexafluoro-2,2-bis(3-amino-4-hydroxyphenyl)propane and 9,9′-bis(3-amino-4-hydroxyphenyl)fluorene; and the diamino compound (c) is one or more selected from the group consisting of 3,4′-diaminodiphenyl ether, 4,4′-diaminodiphenyl ether, 1,3-bis-(3-aminophenoxy)benzene and a silicone diamine.

11. The positive type photosensitive polyimide resin composition according to claim 1 or 10, wherein the diamino compound (c) is 3,4′-diaminodiphenyl ether, 4,4′-diaminodiphenyl ether or 1,3-bis-(3-aminophenoxy)benzene.

12. The positive type photosensitive polyimide resin composition according to claim 1 or 10, wherein the aminophenol compound (b) is 3,3′-diamino-4,4′-dihydroxydiphenylsulfone, 3,3′-diamino-4,4′-dihydroxydiphenyl ether or 1,3-hexafluoro-2,2-bis(3-amino-4-hydroxyphenyl)propane.

13. The positive type photosensitive polyimide resin composition according to claim 10, wherein the tetrabasic acid dianhydride (a) is one or more selected from the group consisting of 3,3′,4,4′-diphenylsulfonetetracarboxylic acid dianhydride, 3,3′,4,4′-benzophenonetetracarboxylic acid dianhydride and 3,3′,4,4′-diphenyl ether tetracarboxylic acid dianhydride; the aminophenol compound (b) is one or more selected from the group consisting of 3,3′-diamino-4,4′-dihydroxydiphenylsulfone, 3,3′-diamino-4,4′-dihydroxydiphenyl ether and 1,3-hexafluoro-2,2-bis(3-amino-4-hydroxyphenyl)propane; and the diamino compound (c) is one or more selected from the group consisting of 3,4′-diaminodiphenyl ether and 1,3-bis-(3-aminophenoxy)benzene.

14. The positive type photosensitive polyimide resin composition according to claim 10 or 13, wherein the epoxy resin (C) is an epoxy resin having a biphenyl skeleton.

15. The positive type photosensitive polyimide resin composition according to any one of claims 1, 10 and 13, wherein the diazo-based positive type photosensitizer (B) is diazonaphthoquinonesulfonyl ester.

16. The positive type photosensitive polyimide resin composition according to any one of claims 1, 10 and 13, being a resin solution comprising a solvent capable of dissolving the phenolic hydroxy group-containing soluble polyimide resin (A).

17. The positive type photosensitive polyimide resin composition according to any one of claims 1, 10 and 13, wherein the phenolic hydroxy group-containing soluble polyimide resin (A) has amino groups at both terminals of the resin.
